(19) United States
(12) Patent Application Publication
(10) Pub. No.: US 2025/0107336 A1
(43) Pub. Date: Mar. 27, 2025

(54) DISPLAY PANELS

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xinkun YAN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/565,113

(22) PCT Filed: Sep. 28, 2023
(86) PCT No.: PCT/CN2023/122647

§ 371 Date: Nov. 29, 2023

(30) Foreign Application Priority Data
Aug. 30, 2023 (CN) 202311123790.8

(51) Int. Cl. H10K 59/122

(52) U.S. Cl. CPC H10K 59/122

(57) ABSTRACT

A display panel is provided by the present disclosure. the display panel includes an array substrate, a planarization layer, a first electrode layer, a spacing layer, a pixel definition layer, a light emitting layer, and a second electrode. The spacing layer includes a plurality of spacing parts disposed between adjacent two first electrodes. Each of the spacing parts includes a groove with an opening direction away from the array substrate and a protrusion extending towards a center of the groove. A maximum depth of the groove is greater than or equal to a sum of thicknesses of the first light emitting sublayer and the charge generation layer. The first light emitting sublayer and the charge generation layer of the light emitting sublayer are disconnected at the spacing parts. The display panel of the present disclosure may improve the problem of light stealing of pixels.

### TECHNICAL FIELD

The present disclosure relates to a field of display technologies, and in particular to display panels.

### BACKGROUND

Organic light emitting diodes (OLEDs) are widely used in the display field due to their excellent performance such as self-illumination, high contrast, wide viewing angle, low power consumption, and bendability, such as in electronic devices such as mobile phones, computers, and televisions.

In order to further reduce power consumption and achieve high brightness, a light-emitting structure in the OLED display panel is provided with a structure with a plurality of light-emitting layers stacked together, and a common functional layer is disposed between adjacent light-emitting layers to connect, forming a series OLED (Tandem OLED).

However, due to the demand for high resolution, a pixel spacing of a display panel may be designed to be very small, resulting in close proximity of adjacent light-emitting structures in the display panel. In addition, a common functional layer disposed continuously in series OLED has strong conductivity, therefore, lateral leakage current is prone to occur in the common functional layer, making it difficult for pixels that should be turned off during display to fully turn off, resulting in the problem of light stealing which seriously affects the display quality of the display panel.

### SUMMARY

The embodiments of the present disclosure provide a display panel, which may improve the problem light stealing of pixels and improve the display quality of the display panel.

The embodiments of the present disclosure provide a display panel. The display panel includes an array substrate, a planarization layer, a first electrode layer, a spacing layer, a pixel definition layer, a light emitting layer, and a second electrode. The planarization layer is disposed on the array substrate. The first electrode layer is disposed on a surface of the planarization layer away from the array substrate and includes a plurality of first electrodes spaced at intervals. The spacing layer is disposed on a surface of the planarization layer away from the array substrate and includes a plurality of spacing parts. One or more of the spacing parts are disposed between adjacent two of the first electrodes. A groove with an opening direction away from the array substrate is defined in each of the spacing parts, and each of the spacing parts includes a protrusion extending towards a center of the groove. The pixel definition layer is disposed on a surface of the first electrode layer away from the array substrate and a surface of the spacing layer away from the array substrate. A plurality of first openings and a plurality of second openings are defined on a surface of the pixel definition layer away from the planarization layer. Each of the first opening exposes at least a part of corresponding one of the first electrodes. Each of the second openings is in communication with corresponding groove. The light emitting layer is disposed on a surface of the pixel definition layer away from the array substrate and includes a first light emitting sublayer, a charge generation layer, and a second light emitting sublayer stacked in sequence. The second electrode layer is disposed on a surface of the light emitting layer away from the array substrate. A maximum depth of the groove is greater than or equal to a sum of thicknesses of the first light emitting sublayer and the charge generation layer. At least the first light emitting sublayer and the charge generation layer of the light emitting sublayer are disconnected at the spacing parts.

In an embodiment of the present disclosure, the maximum depth of the groove is less than or equal to a thickness of the light emitting layer.

In an embodiment of the present disclosure, the second electrode layer is continuous at the spacing parts.

In an embodiment of the present disclosure, the spacing layer includes a first spacing sublayer and a second spacing sublayer. The first spacing sublayer is disposed on a surface of the second spacing sublayer away from the planarization layer. A plurality of third openings corresponding to the spacing parts are defined in the first spacing sublayer. A plurality of fourth openings corresponding to the spacing parts are defined in the second spacing sublayer. The groove is provided with one of the third openings and one of the fourth openings. The one of the third openings is in communication with the one of the fourth opening.

In an embodiment of the present disclosure, a thickness of the second spacing sublayer ranges from 0.05 microns to 0.4 microns.

In an embodiment of the present disclosure, an opening size of one end of one of the fourth openings close to the first spacing sublayer is smaller than an opening size of one of the third openings.

In an embodiment of the present disclosure, an etching rate of the first spacing sublayer is lower than an etching rate of the second spacing sublayer.

In an embodiment of the present disclosure, an included angle between a connecting line at both ends of a sidewall of one of the third openings of the first spacing sublayer and a surface of the first spacing sublayer close to the array substrate is a first included angle, an included angle between a connecting line at both ends of a sidewall of one of the fourth openings of the second spacing sublayer and a surface of the second spacing sublayer close to the array substrate is a second included angle, and the first included angle is greater than the second included angle.

In an embodiment of the present disclosure, the spacing layer further includes a third spacing sublayer. The third spacing sublayer is disposed between the second spacing sublayer and the planarization layer. A plurality of sub grooves corresponding to the spacing parts are defined in the third spacing sublayer. The groove is provided with one of the sub grooves. An opening of each of the sub grooves faces the second spacing sublayer and is in communication with corresponding one of the fourth openings.

In an embodiment of the present disclosure, the sidewall of the one of the fourth openings of the second spacing sublayer includes a first curved surface, one of the sub grooves of the third spacing sublayer includes a second curved surface, and a curvature radius of the second curved surface is greater than a curvature radius of the first curved surface.

In an embodiment of the present disclosure, the second curved surface is continuous with the first curved surface adjacent to the second curved surface.

In an embodiment of the present disclosure, an etching rate of the third spacing sublayer is lower than an etching rate of the second spacing sublayer.

In an embodiment of the present disclosure, an included angle between a connecting line at both ends of a sidewall of one of the third openings of the first spacing sublayer and a surface of the first spacing sublayer close to the array substrate is the first included angle, an included angle between a connecting line at both ends of a sidewall of one of the fourth openings of the second spacing sublayer and a surface of the second spacing sublayer close to the array substrate is a second included angle, an included angle between a connecting line at both ends of a sidewall of one of the sub grooves of the third spacing sublayer and a surface of the third spacing sublayer close to the array substrate is a third included angle, the first included angle is greater than the second included angle, and the second included angle is greater than the third included angle.

In an embodiment of the present disclosure, a thickness of the third spacing sublayer is greater than 3 nanometers.

In an embodiment of the present disclosure, a distance between an edge of the protrusion of the first spacing sublayer towards the center of the groove and an edge of one end of one of the fourth openings close to the first spacing sublayer is greater than or equal to 1 micron.

In an embodiment of the present disclosure, a thickness of the first spacing sublayer ranges from 0.01 microns to 0.1 microns.

In an embodiment of the present disclosure, one or more of the spacing parts surround corresponding one of the first electrodes.

In an embodiment of the present disclosure, the one or more of the spacing parts are completely enclosed on a peripheral side of one of the first electrodes.

In an embodiment of the present disclosure, the one or more of the spacing parts are partially enclosed on a peripheral side of one of the first electrodes.

In an embodiment of the present disclosure, two of the second openings are defined between adjacent two of the first openings, two of the spacing parts are disposed between adjacent two of the first electrodes, and one of the second opening is in communication with the corresponding groove of one of the spacing parts.

### BENEFICIAL EFFECTS

In the display panel provided by the embodiments of the present disclosure, one or more of the spacing parts are disposed between adjacent two of the first electrodes. A groove with an opening direction away from the array substrate is defined in each of the spacing parts. Each of the spacing parts includes a protrusion extending towards a center of the groove. A maximum depth of the groove is greater than or equal to a sum of thicknesses of the first light emitting sublayer and the charge generation layer. In the light emitting layer, at least the first light emitting sublayer and the charge generation layer are disconnected at the spacing parts, thereby isolating the conduction path of lateral leakage current between pixels, improving the crosstalk problem between pixels caused by the lateral leakage current in the display panel, thereby improving the problem of light stealing of pixels and improving the display quality of the display panel.

### BRIEF DESCRIPTION OF THE DRAWINGS

FIG. 1 is a schematic view of a first cross-sectional structure of a display panel provided by an embodiment of the present disclosure.

FIG. 2 is a schematic view of a structure of a light emitting layer of the display panel provided by an embodiment of the present disclosure.

FIG. 3 is a schematic view of a second cross-sectional structure of the display panel provided by an embodiment of the present disclosure.

FIG. 4 is a schematic view of a structure of a spacing layer of the display panel shown in FIG. 1.

FIG. 5 is a top view of the display panel shown in FIG. 1.

FIG. 6 is a schematic view of a third cross-sectional structure of the display panel provided by an embodiment of the present disclosure.

FIG. 7 is a top view of the display panel shown in FIG. 6.

FIG. 8 is a flowchart of a manufacturing method of the display panel provided by an embodiment of the present disclosure.

### DETAILED DESCRIPTION

In order to make the embodiments of the present disclosure clearer, the technical solutions in the embodiments of the present disclosure will be described clearly and completely hereafter with reference to the accompanying drawings.

In the present disclosure, unless stated to the contrary, the used orientation words used such as “up” and “down” generally refer to up and down in the actual use or working state of the device, and the directional words used such as “inside” and “outside” refer to the inside and outside positions relative to the contour of each device itself. In the description of the present disclosure, unless otherwise specifically defined, “a plurality of” means at least two, such as two, three, etc. Terms such as “first” and “second” are used herein for purposes of description, and should not be interpreted as indication or implication of relative importance, or implied indication of a number of the technical features.

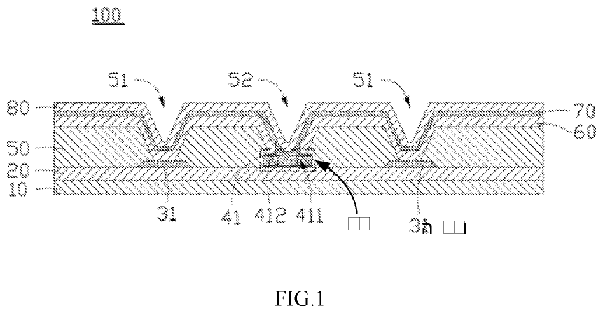

Please refer to FIG. 1, an embodiment of the present disclosure provides a display panel 100, which includes an array substrate 10, a planarization layer 20, a first electrode layer 30, a spacing layer 40, a pixel definition layer 50, a light emitting layer 60, and a second electrode layer 70.

Specifically, the planarization layer 20 is disposed on the array substrate 10 to provide a flat surface for the subsequent setting of the first electrode layer 30. A material of the planarization layer 20 may be an organic material with low dielectric constant, such as polyimide.

The first electrode layer 30 is disposed on a surface of the planarization layer 20 away from the array substrate 10. The first electrode layer 30 includes a plurality of first electrodes 31 spaced apart. The first electrode 31 may be an anode, and materials with high work function may be selected to improve hole injection efficiency, such as gold, platinum, titanium, silver, indium tin oxide (ITO), zinc tin oxide (IZO), or transparent conductive polymers (such as polyaniline).

The spacing layer 40 is disposed on a surface of the planarization layer 20 away from the array substrate 10. The spacing layer 40 includes a plurality of spacing parts 41, one or more of the spacing parts 41 are disposed between adjacent two first electrodes 31. The spacing part includes a groove 411 with an opening direction away from the array substrate 10 and a protrusion part 412 extending towards the center of the groove 411. Due to the obstruction of the protrusion 412, when the light emitting layer 60 is subsequently formed, there will be no deposition of the light emitting layer 60 in the area falling into the groove 411 of a projection of the protrusion 412 on the array substrate 10, making it easier to disconnect the light emitting layer 60 at the spacing parts 41.

The pixel definition layer 50 is disposed on surfaces of the first electrode layer 30 and the interlayer 40 away from the array substrate 10. A surface of the pixel definition layer 50 away from the planarization layer 30 is provided with a plurality of first openings 51 and a plurality of second openings 52. The first opening 51 exposes at least a part of the corresponding first electrode 31, and the second opening 52 is in communication with the corresponding groove 411. A material of the pixel definition layer 50 may be hexamethyldisiloxane, epoxy resin, or polyimide, as well as other silicone adhesive materials with a light transmittance of over 90%, or other organic adhesive materials with a light transmittance greater than 80% and slightly higher bending strength. In addition, a plurality of support columns PS are disposed on the pixel definition layer 50, the support columns PS are used to support the mask during an evaporation process. In order not to affect the definition of the second openings 52, the second openings 52 should avoid the support columns PS.

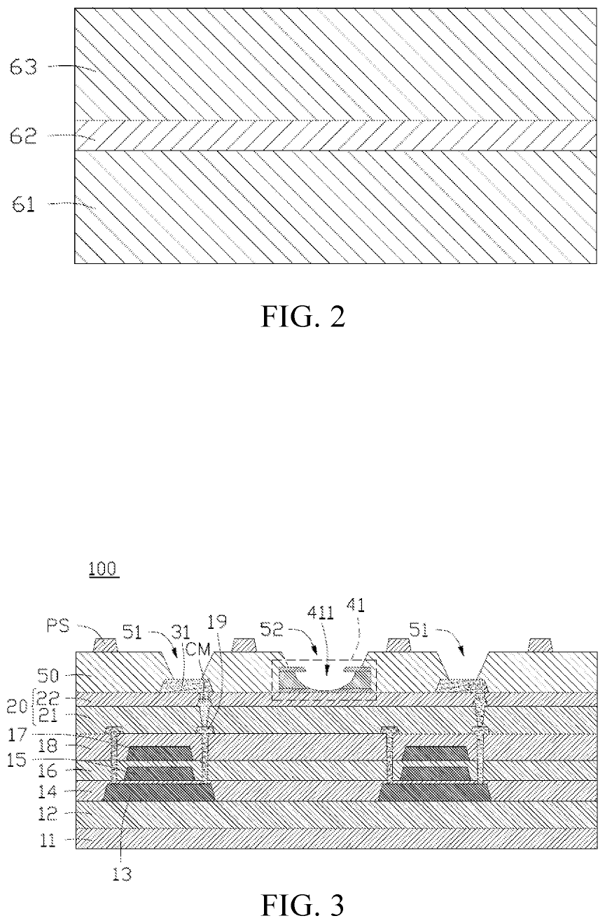

The light emitting layer 60 is disposed on a surface of the pixel definition layer 50 away from the array substrate 10. As shown in FIG. 2, the light emitting layer 60 includes a first light emitting sublayer 61, a charge generation layer 62, and a second light emitting sublayer 63 stacked in sequence. The first light emitting sublayer 61 and the second light emitting sublayer 62 are used for displaying luminescence, which may include film layers such as an electron injection layer, an electron transport layer, an organic light emitting material layer, a hole transport layer, and a hole injection layer. The charge generation layer 62 disposed between the first light emitting sublayer 61 and the second light emitting sublayer 62 is used to connect the first light emitting layer 521 and the second light emitting layer 523, forming a series OLED device to achieve the effect of reducing power consumption and improving brightness. The charge generation layer 62 may be formed by evaporation with an open mask. The charge generation layer 62 generally includes organic materials with high carrier transport rates and is doped with active metals such as lithium and ytterbium, so that the charge generation layer 62 has strong conductivity and is able to achieve efficient conduction between the first light emitting sublayer 61 and the second light emitting sublayer 62, but also is prone to generating transverse conduction currents.

The second electrode layer 70 is disposed on a surface of the light emitting layer 60 away from the array substrate 10, forming an electric field with the first electrode layer 30 to drive the light emitting layer 60 to emit light. The second electrode layer 70 may be a cathode and may be selected from materials with lower work functions for electron injection, such as one of silver (Ag), aluminum (Al), lithium (Li), magnesium (Mg), ytterbium (Yb), calcium (Ca), indium (In), or other metal materials. It may also be an alloy of the aforementioned metal materials, such as magnesium silver alloy (Mg/Ag), or lithium aluminum alloy (Li/Al). The second electrode layer 70 may not be disconnected (continuous) at the spacing parts 41. Specifically, the continuous setting of the second electrode layer 70 may reduce its resistance, facilitate the transmission of current in the second electrode layer, improve the response of the display panel 100, and thereby enhance the display effect of the display panel 100.

Specifically, a maximum depth of groove 411 is greater than or equal to a sum of the thicknesses of the first light emitting sublayer 61 and the charge generation layer 62. In the light emitting layer 60, at least the first light emitting sublayer 61 and the charge generation layer 62 are disconnected at the spacing parts 41. By this way, the lateral conduction path of the current in the charge generation layer 62 is isolated, and the crosstalk problem between pixels caused by the lateral leakage current in the display panel 100 is improved, thereby improving the problem of light stealing of pixels and improving the display quality of the display panel 100.

The maximum depth of groove 411 may be less than or equal to the thickness of the light emitting layer 60. By this way, after the formation of the light emitting layer 60, a segment difference appearing on the surface of the light emitting layer 60 away from the array substrate 10 at the spacing part 41 will not separate the second electrode layer 70 formed subsequently, thereby ensuring the continuity of the the second electrode layer 70 formed subsequently and improving the display effect of the display panel 100.

Please continue to refer to FIG. 1. The display panel 100 further includes an encapsulation layer 80 located on a surface of the second electrode layer 70 away from the array substrate 10 to isolate external water vapor from penetrating into the interior of the display panel 100. The encapsulation layer 80 may include alternating layers of organic layers and inorganic layers. A material of the organic layer may be any of them, such as polyethylene terephthalate, polyimide, polycarbonate (PC), epoxy resin, polyethylene (PE), or polyacrylate (PA). A material of the inorganic layer may be any of them, such as silicon nitride, alumina, silicon oxide, or titanium oxide.

Please refer to FIG. 3. The array substrate 10 may include a substrate 11 and a buffer layer 12, an active layer 13, a first insulation layer 14, a first metal layer 15, a second insulation layer 16, a second metal layer 17, a third insulation layer 18, and a third metal layer 19 sequentially disposed on the substrate 11.

The substrate 11 is used to support the various layer structures disposed on the substrate 11. The substrate 11 may be a rigid substrate such as a glass substrate, or a flexible substrate. A material of the flexible substrate includes but are not limited to polyimide (PI), polyethylene naphthalate (PEN), polyethylene terephthalate (PET), polyetherimide (PEI), etc. The substrate 11 may include a multi-layer stacked structure. Specifically, the substrate 11 may include a first flexible substrate, an intermediate layer, and a second flexible substrate stacked in sequence. The first flexible substrate and the second flexible substrate may be formed by polyimide, and the intermediate layer may be formed by inorganic materials such as silicon nitride and silicon oxide.

The buffer layer 12 is disposed on the substrate 11 to prevent impurities and water vapor from infiltrating from the substrate 11, and to provide a flat surface for the subsequent formation of the film layer. The buffer layer 12 includes inorganic insulating materials such as silicon nitride, silicon oxide, or silicon nitride. To further enhance the effectiveness of blocking impurities, water vapor, and flattening, a barrier layer may be disposed between the buffer layer 12 and the substrate 11. The buffer layer 12 includes inorganic insulation materials such as silicon nitride, silicon oxide, or silicon nitride. Specifically, the barrier layer may include a plurality of sublayer structures. A sublayer close to the substrate 11 is formed by silicon oxide to enhance the bonding performance between the barrier layer and the substrate 11. The sublayer close to the buffer layer 12 is formed by silicon nitride to enhance the bonding performance between the barrier layer and the buffer layer 12.

The active layer 13 is disposed on the buffer layer 12. A material of the active layer 13 may be metal oxide semiconductors such as polycrystalline silicon (P-Si) or indium gallium zinc oxide (IGZO). In order to reduce the impact of light on the active layer 13, a shading layer may further be disposed on or below the buffer layer 12, so that a vertical projection of the shading layer and the active layer 13 on the array substrate 10 overlaps with each other, thereby reducing the exposure of light to the active layer 13 and ensuring the stable performance of the array substrate 10.

The first insulation layer 14 is disposed on the active layer 13, and a material of the first insulation layer 14 may be silicon nitride, silicon oxide, or a layered structure of silicon nitride and silicon oxide.

The first metal layer 15 is disposed on the first insulation layer 14 and may be patterned to form a first gate. Materials of the first metal layer 15 may include molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), copper (Cu) or its alloys. The first metal layer 15 may include a single layer or a plurality of layers of metal structure.

The second insulation layer 16 is disposed on the first metal layer 15. A material of the second insulation layer 16 may be silicon nitride, silicon oxide, or a layered structure of silicon nitride and silicon oxide.

The second metal layer 17 is disposed on the second insulation layer 16 and may be patterned to form a second gate. Specifically, the second metal layer 17 is disposed opposite to the first metal layer 15, forming a dual gate structure. Materials of the second metal layer 17 may include molybdenum, aluminum, platinum, palladium, silver, magnesium, gold, nickel, neodymium, iridium, chromium, titanium, tantalum, tungsten, copper or its alloys. The second metal layer 17 may include a single layer or a plurality of layers of metal structures.

The third insulation layer 18 is disposed on the second metal layer 17. A material of the third insulation layer 18 may be silicon nitride, silicon oxide, or a layered structure of silicon nitride and silicon oxide.

The third metal layer 19 is disposed on the third insulation layer 18, and may be patterned to form a source metal layer and a drain metal layer spaced at intervals. Specifically, the third metal layer 19 is connected to the active layer 13 through a via hole. Therefore, the first metal layer 15, the second metal layer 17, the third metal layer 19, and the active layer 13 together form a thin film transistor. Materials of the third metal layer 19 may include molybdenum, aluminum, platinum, palladium, silver, magnesium, gold, nickel, neodymium, iridium, chromium, titanium, tantalum, tungsten, copper or its alloys. The third metal layer 19 may include a single layer or a plurality of layers of metal structures.

Please continue to refer to FIG. 3. The planarization layer 20 disposed on the array substrate 10 may include a first planarization layer 21 and a second planarization layer 22 to further improve the flatness of the surface and provide a smoother surface for the first electrode layer 30 formed subsequently. When the planarization layer 20 includes a multi-layer structure, a contact metal layer CM may further be disposed between the first electrode 31 and the third metal layer 19. The first electrode 31 is connected to the contact metal layer CM. The contact metal layer CM is connected to the third metal layer 19, which is more conducive to achieving wire connection between the multi-layer film layer structures.

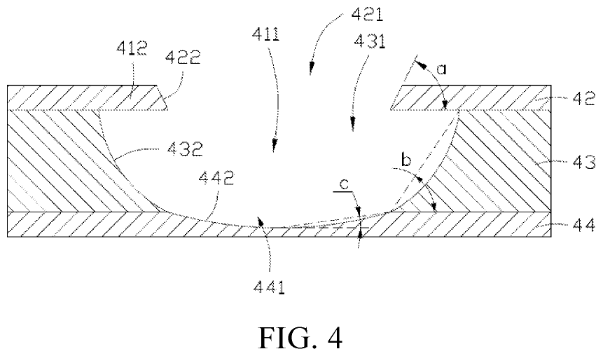

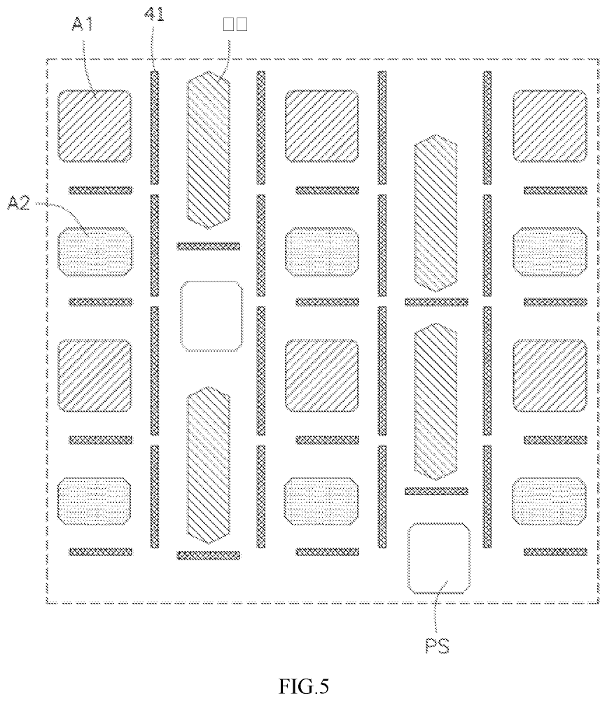

Please refer to FIG. 4. The spacing layer 40 includes a first spacing sublayer 42 and a second spacing sublayer 43. The first spacing sublayer 41 is disposed on a surface of the second spacing sublayer 43 away from the planarization layer 20. The first spacing sublayer 42 includes a plurality of third openings 421 corresponding to the spacing part 41. The second spacing sublayer 43 includes a plurality of fourth openings 431 corresponding to the spacing part 41. The third opening 421 is in communication with the fourth opening 431. An opening size of one end of the fourth opening 431 close to the first spacing sublayer 42 is smaller than an opening size of the third opening 421. By this way, the first spacing sublayer 42 may be enabled to have a protrusion 412 extending towards the center of the groove 411, which may block the deposition of the light emitting layer 60 when subsequently forming the light emitting layer 60, thereby improving the spacing effect of the space parts 41 on the light emitting layer 60.

The groove 411 may be provided with a third opening 421 and a fourth opening 431. An etching rate of the first spacing sublayer 42 may be lower than that of the second spacing sublayer 43. By this way, the etching process may be used once, and the removed material of the second spacing sublayer 43 may be more than the removed material of the first spacing sublayer 42 by etching in the same etching process, which is more conducive to forming a protrusion 412 extending towards the center of the groove 411, simplifying the process of forming the spacing layer 40 and reducing the process difficulty.

Specifically, a material of the first spacing sublayer 42 may be silicon nitride. A material of the second spacing sublayer 43 may be silicon oxide. Due to the lower etching rate of silicon nitride than that of silicon oxide, wet etching may be used to form the third openings 421 and the fourth openings 431. The third opening 421 and the fourth opening 431 are in communication to form the groove 411. The isotropy of the wet etching process is utilized to remove more materials from the second spacing sublayer 43 than the first spacing sublayer 42 in one etching process, and the protrusion 412 extending towards the center of the groove 411 is ultimately formed, greatly simplifying the process of forming the spacing layer 40 and reducing the process difficulty. Moreover, the etching uniformity of inorganic materials such as silicon nitride and silicon oxide is significantly better than that of organic materials. The materials of the first spacing sublayer 42 and the second spacing sublayer 43 are respectively selected from silicon nitride and silicon oxide, giving the spacing layer 40 a more detailed and uniform spacing morphology, further improving the isolation effect of the spacing layer 40 on the light emitting layer 60 and the overall reliability of the display panel 100. The thickness of the second spacing sublayer 43 may be adjusted based on the specific thickness of the light emitting layer 60, so that the light emitting layer 60 may be disconnected at the spacing parts 41. The specific thickness of the second spacing sublayer 43 may range from 0.05 microns to 0.4 microns.

An included angle between a connecting line at both ends of a sidewall of the third opening 421 of the first spacing sublayer 42 and a surface of the first spacing sublayer 42 close to the array substrate 10 is a first included angle a. An included angle between a connecting line at both ends of a sidewall of the fourth opening 431 of the second spacing sublayer 43 and a surface of the second spacing sublayer 43 close to the array substrate 10 is a second included angle b. The first included angle a is greater than the second included angle b. By this way, the spacing effect of the first spacing sublayer 42 on the light emitting layer 60 may be further enhanced, thereby further enhancing the isolation effect of the spacing layer 40 on the lateral current.

The spacing layer 40 may further include a third spacing sublayer 44. The third spacing sublayer 44 is disposed between the second spacing sublayer 43 and the planarization layer 20. A plurality of sub grooves 441 corresponding to the spacing part 41 are defined in the third spacing sublayer 44. An opening of the sub groove 441 facing the second spacing sublayer 43 and is in communication with the corresponding fourth opening 431. The groove 411 is provided with a third opening 421, a fourth opening 431, and a sub groove 441. The setting of the third spacing sublayer 44 may reduce the adverse impact of over etching on the flatness of the planarization layer 20, thereby improving the flatness of the film layer formed subsequent, and improving the reliability and display effect of the display panel 100. In addition, the obstruction of the third spacing sublayer 44 further increases the adjustment range of etching time, which is more conducive to adjusting the depth of lateral etching for the first spacing sublayer 42 and the second spacing sublayer 43, ensuring the spacing effect of the spacing layer 40 on the light emitting layer 60.

The side wall of the fourth opening 431 of the second spacing sublayer 43 may include a first curved surface 432, the sub groove 441 of the third spacing sublayer 44 may include a second curved surface 442, and a curvature radius of the second curved surface 442 is greater than that of the first curved surface 432. By this way, there may be a small segment difference at the third spacing sublayer 44, thereby further reducing the segment difference of a surface of the light emitting layer 60 away from the array substrate 10 appearing at the spacing 41. This is more conducive to the continuity of the second electrode layer 70 at the spacing parts 41, thereby improving the display effect of the display panel 100.

The second curved surface 442 may be continuous with its adjacent first curved surface 432. This setting may minimize the segment difference between the third spacing sublayer 44 and the second spacing sublayer 43, thereby further reducing the segment difference of the surface the emitting layer 60 away from the array substrate 10 appearing at the spacing part 41 after the formation of the emitting layer 60, which is beneficial to the continuity of the second electrode layer 70 formed subsequently at the spacing parts 41 and to improve the display effect of the display panel 100.

The etching rate of the third spacing sublayer 44 may be lower than that of the second spacing sublayer 43. By this way, the etching process may be used once, and the removed material of the third spacing sublayer 44 may be less than the removed material of the second spacing sublayer 43 by etching in the same etching process, which simplifies the process, reduces process difficulty, and is more conducive to making the curvature radius of the second arc surface 442 greater than the curvature radius of the first arc surface 432. Therefore, the segment difference of the surface of the emitting layer 60 away from the array substrate 10 at the spacing part 41 may be reduced. In addition, the third spacing sublayer 44 with a smaller etching rate is more suitable as an etching barrier layer, further reducing the adverse impact of over etching on the flatness of the planarization layer 20. Specifically, a material of the second spacing sublayer 43 may be silicon oxide. A material of the third spacing sublayer 44 may be silicon nitride or silicon oxynitride. A thickness of the third spacing sublayer 44 may be greater than 3 nanometers. From the perspective of further improving the uniformity of film formation, the thickness of the third spacing sublayer 44 is greater than 20 nanometers.

An included angle between a connecting line at both ends of a sidewall of the third opening 421 of the first spacing sublayer 42 and a surface of the first spacing sublayer 42 close to the array substrate is the first included angle a. An included angle between a connecting line at both ends of a sidewall of the fourth opening 431 of the second spacing sublayer 43 and a surface of the second spacing sublayer 43 close to the array substrate 10 is a second included angle b. An included angle between a connecting line at both ends of a sidewall of the sub groove 441 of the third spacing sublayer 44 and a surface of the third spacing sublayer 44 close to the array substrate 10 is a third included angle c, the first included angle a is greater than the second included angle b, and the second included angle b is greater than the third included angle c. This setting further enhances the spacing effect of the first spacing sublayer 42 on the light emitting layer 60 formed subsequent, thereby further enhancing the isolation effect of the spacing layer 40 on the lateral current in the light emitting layer 60.

A distance between an edge of the protrusion 412 of the first spacing sublayer 42 towards the center of the groove 411 and an edge of the fourth opening 431 close to the first spacing sublayer 42 may be greater than or equal to 1 micron. This setting may reduce the impact caused by process accuracy errors. Even if there is a slight deviation in the specific position of the groove 411 due to process accuracy errors, it will not affect the morphology formation of the protruding part 412, further ensuring the spacing effect of the spacing parts 41. From the perspective of considering both the spacing effect and the lightweight performance of the display panel 100, the thickness of the first spacing sublayer 42 may range from 0.01 microns to 0.1 microns.

One of more of the spacing parts 41 may surround the corresponding first electrode 31. Please refer to FIG. 5, the display panel 100 includes a plurality of first sub pixels A1, a plurality of second sub pixels A2, and a plurality of third sub pixels A3. The first subs pixel A1, the second sub pixels A2, and the third sub pixels A3 are disposed in the first openings 51. The first sub pixels A1, the second sub pixels A2, and the third sub pixels A3 include a first electrode 31, a light emitting layer 60, and a second electrode layer 70 that are sequentially stacked. In other words, the spacing parts 41 may be disposed around the first sub pixel A1, around the second sub pixel A2, or around the third sub pixel A3. By this way, the spacing parts 41 may isolate the latreal current in the charge generation layer between one sub pixel and adjacent other sub pixel of the display panel, improving the crosstalk problem between sub pixels. Therefore, the problem of light stealing of sub pixels during displaying is improved, and the display quality of the display panel 100 is improved. The spacing parts 41 are disposed corresponding to the specific pixel layout structure, ensuring that the spacing parts 41 are disposed around sub pixels. Specifically, the spacing parts 41 may be completely enclosed on the peripheral side of the first electrode 31, that is, the spacing parts 41 disposed on the peripheral side of the first electrode 31 are continuous. The spacing parts 41 may also be partially enclosed on the peripheral side of the first electrode 31, that is, the spacing parts 41 disposed on the peripheral side of the first electrode 31 are intermittently disposed with notches.

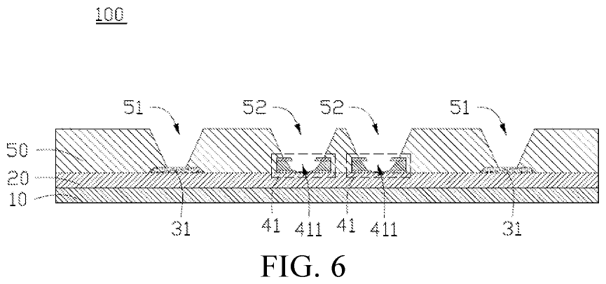

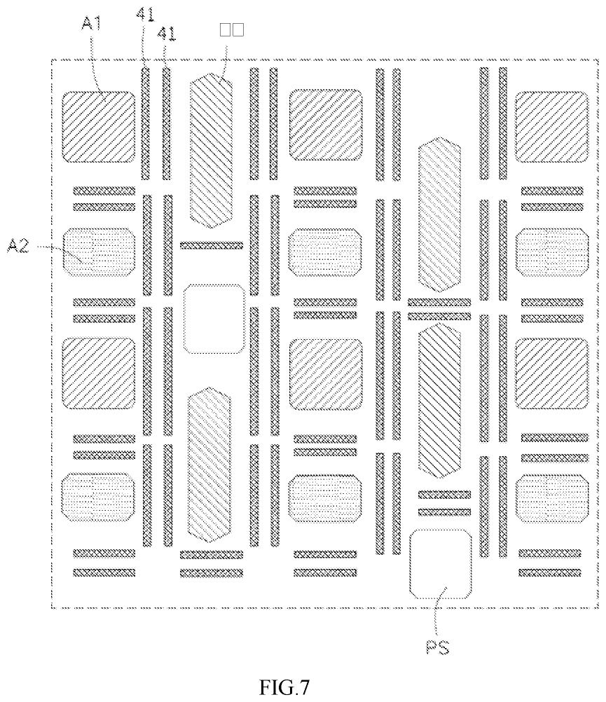

Please refer to FIGS. 6 and 7, the second cross-sectional schematic view of the display panel 100 provided in the embodiment of the present disclosure differs from the cross-sectional schematic view of the display panel 100 shown in FIG. 1 in that there are two second openings 52 between the adjacent two first openings 51 and two spacing parts 41 between the adjacent two first electrodes 31. A second opening 52 is in communication with the groove 411 of a corresponding spacing part 41. A plurality of the spacing parts 41 are disposed between the adjacent two first electrodes 31, which further enhances the spacing effect of the spacing layer 40 on the light emitting layer 60, thereby further enhancing the isolation effect the spacing layer 40 on the lateral current of the light emitting layer 60.

The display panel 100 provided in the above embodiments may be applied to various display devices to improve their display quality. The display devices include but are not limited to smartwatches, mobile phones, tablets, laptops, etc.

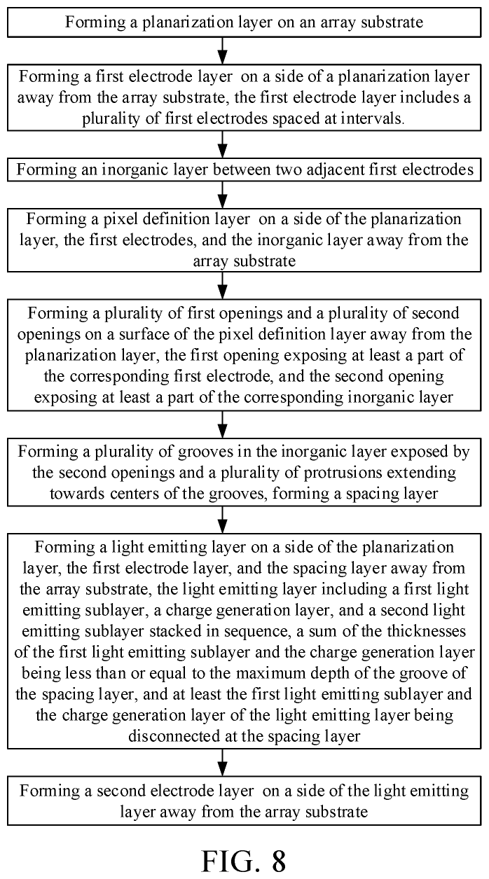

Please refer to FIG. 8. The embodiments of the present disclosure further provide a manufacturing method of a display panel, including the following steps S1 to S6.

At step S1, a planarization layer is formed on the array substrate.

Specifically, the material of the planarization layer may be an organic material with low dielectric constant, such as polyimide. In order to provide a smoother surface for the film layer formed subsequently, the planarization layer may include a first planarization layer and a second planarization layer.

At step S2, a first electrode layer is formed on a surface of a planarization layer away from the array substrate. The first electrode layer includes a plurality of first electrodes spaced at intervals.

The material of the first electrode may be selected from materials such as gold, platinum, titanium, silver, indium tin oxide, zinc tin oxide, or transparent conductive polymers such as polyaniline. Specifically, a layer of first electrode material may be formed on the planarization layer first, and then patterned to form a plurality of the first electrodes spaced at intervals.

At step S3, an inorganic layer is formed between two adjacent first electrodes.

Specifically, a chemical vapor deposition (CVD) process may be used to deposit a layer of inorganic layer material on the planarization layer, and then patterned to form the inorganic layer between adjacent first electrodes.

At step S4, a pixel definition layer is formed on surfaces of the planarization layer, the first electrodes, and the inorganic layer away from the array substrate.

A material of the pixel definition layer may be hexamethyldisiloxane, epoxy resin, or polyimide, as well as other silicone adhesive materials with a light transmittance of over 90%, or other organic adhesive materials with a light transmittance greater than 80% and slightly higher bending strength.

At step S5, a plurality of first openings and a plurality of second openings are formed on a surface of the pixel definition layer away from the planarization layer. The first opening exposes at least a part of the corresponding first electrode, and the second opening exposes at least a part of the corresponding inorganic layer.

Specifically, a half tone mask (HTM) process may be used to define the first openings in the pixel definition layer at the position of the first electrode to expose at least a part of the corresponding first electrode. The second openings in the pixel definition layer at the position of the inorganic layer are defined to expose at least a part of the corresponding inorganic layer.

At step S6, a spacing layer is formed on the inorganic layer exposed by the second openings. The spacing layer includes a plurality of spacing parts, one or more spacing parts are disposed between adjacent two first electrodes. A groove with an opening direction away from the array substrate is defined in the spacing part. The spacing part includes a protrusion extending towards the center of the groove.

The spacing layer may include a first spacing sublayer, a second spacing sublayer, and a third spacing sublayer stacked in sequence. Correspondingly, the inorganic layer includes a first inorganic layer, a second inorganic layer, and a third inorganic layer arranged stacked sequence. The first spacing sublayer, the second spacing sublayer, and the third spacing sublayer are respectively formed by the patterning process of the first inorganic layer, the second inorganic layer, and the third inorganic layer. The first spacing sublayer has protrusions relative to the second spacing sublayer in the direction towards the center of the groove. In the subsequent formation of the light emitting layer, due to the obstruction of the protrusion, there will be no deposition of the light emitting layer in the area where the vertical projection of the protrusion on the array substrate falls into the groove, making it easy to disconnect the light emitting layer at the spacing layer. The conduction of lateral current in the light emitting layer, especially in the charge generation layer, is interrupted at the spacing layer, thereby improving the crosstalk problem between pixels caused by lateral leakage current.

Specifically, the etching rate of the first inorganic layer may be lower than that of the second inorganic layer. For example, the material of the first inorganic layer is silicon nitride, and the material of the second inorganic layer is silicon oxide. Thus, wet etching may be used to etch the first inorganic layer and the second inorganic layer to form the grooves. the isotropy of the wet etching process may be utilized to remove more materials from the second inorganic layer than from the first inorganic layer in the same etching process, ultimately forming a protrusion of the first spacing sublayer relative to the second spacing sublayer in the direction towards the center of the groove, thereby simplifying the formation process of the spacing layer and reducing the process difficulty.

The third spacing sublayer is disposed between the second spacing sublayer and the planarization layer. The etching rate of the third spacing sublayer may be lower than that of the second spacing sublayer. For example, the material of the second spacing sublayer is silicon oxide, and the material of the third spacing sublayer is silicon nitride or silicon oxynitride. The third spacing sublayer serves as an etching barrier layer, which can reduce the adverse impact of over etching on the flatness of the planarization layer during etching of the first inorganic layer and the second inorganic layer. Therefore, the setting of the third spacing sublayer may improve the flatness of the film layer formed subsequently, enhance the reliability and display effect of the display panel. In addition, the obstruction of the third spacing sublayer further increases the adjustment range of etching time, which is more conducive to adjusting the depth of lateral etching for the first spacing sublayer and the second spacing sublayer, ensuring the spacing effect of the spacing layer on the light emitting layer.

At step S7, a light emitting layer is formed on surfaces on the planarization layer, the first electrode layer, and the spacing layer away from the array substrate. The light emitting layer includes a first light emitting sublayer, a charge generation layer, and a second light emitting sublayer stacked in sequence. A sum of the thicknesses of the first light emitting sublayer and the charge generation layer is less than or equal to the maximum depth of the groove of the spacing layer. In the light emitting layer, at least the first light emitting sublayer and the charge generation layer are disconnected at the spacing layer.

Specifically, the first light emitting sublayer and the second light emitting sublayer may include film layers such as an electron injection layer, an electron transport layer, an organic luminescent material layer, a hole transport layer, and a hole injection layer. The charge generation layer may be formed by open mask evaporation. The charge generation layer is disposed between the first light emitting sublayer and the second light emitting sublayer. The charge generation layer is used to connect the first light emitting sublayer and the second light emitting sublayer, to form a series OLED device to reduce power consumption and improve brightness. Specifically, the charge generation layer includes organic materials with high carrier transfer rates and is doped with active metals such as lithium or ytterbium, thus possessing strong conductivity and being able to achieve efficient conduction between a plurality of stacked organic light emitting layers. However, it is also prone to generating laterally conductive currents. Due to the fact that the sum of the thicknesses of the first light emitting sublayer and the charge generation layer is less than or equal to the maximum depth of the groove of the spacing layer, in the light emitting layer, at least the first light emitting sublayer and the charge generation layer are disconnected at the spacing layer, blocking the conduction path of the lateral leakage current, thereby improving the crosstalk problem between pixels caused by the lateral leakage current, improving the problem of light stealing of pixels, and improving the display quality of the display panel.

At step S8, a second electrode layer is formed on a surface of the light emitting layer away from the array substrate.

Materials of the second electrode layer may be selected from materials with lower work functions for electron injection, such as silver (Ag), aluminum (Al), lithium (Li), magnesium (Mg), ytterbium (Yb), calcium (Ca), indium (In), or other metal materials. It can also be an alloy of the aforementioned metal materials, such as magnesium silver alloy (Mg/Ag) or lithium aluminum alloy (Li/Al). The second electrode layer may be not disconnected (continuous) at the spacing parts to reduce its resistance, facilitate the transmission of current in the second electrode layer, improving the response of the display panel, and thus enhance the display effect of the display panel.

The above provides a detailed introduction to the display panel provided by the embodiments of the present disclosure. The explanation of the above embodiments is only used to help understand the methods and core ideas of the present disclosure, and should not be understood as a limitation on the scope of protection of the present disclosure.

1. A display panel, characterized in that wherein the display panel comprises:
an array substrate;
a planarization layer disposed on the array substrate;
a first electrode layer disposed on a surface of the planarization layer away from the array substrate and comprising a plurality of first electrodes spaced at intervals;
a spacing layer disposed on a surface of the planarization layer away from the array substrate and comprising a plurality of spacing parts, wherein one or more of the spacing parts are disposed between adjacent two of the first electrodes, a groove with an opening direction away from the array substrate is defined in each of the spacing parts, and each of the spacing parts comprises a protrusion extending towards a center of the groove;
a pixel definition layer disposed on a surface of the first electrode layer away from the array substrate and a surface of the spacing layer away from the array substrate, wherein a plurality of first openings and a plurality of second openings are defined on a surface of the pixel definition layer away from the planarization layer, each of the first opening exposes at least a part of corresponding one of the first electrodes, and each of the second openings is in communication with corresponding groove;
a light emitting layer disposed on a surface of the pixel definition layer away from the array substrate and comprising a first light emitting sublayer, a charge generation layer, and a second light emitting sublayer stacked in sequence; and
a second electrode layer disposed on a surface of the light emitting layer away from from the array substrate;
wherein a maximum depth of the groove is greater than or equal to a sum of thicknesses of the first light emitting sublayer and the charge generation layer, and at least the first light emitting sublayer and the charge generation layer of the light emitting sublayer are disconnected at the spacing parts.

2. The display panel of claim 1, wherein the maximum depth of the groove is less than or equal to a thickness of the light emitting layer.

3. The display panel of claim 2, wherein the second electrode layer is continuous at the spacing parts.

4. The display panel of claim 1, wherein the spacing layer comprises a first spacing sublayer and a second spacing sublayer, the first spacing sublayer is disposed on a surface of the second spacing sublayer away from the planarization layer, a plurality of third openings corresponding to the spacing parts are defined in the first spacing sublayer, a plurality of fourth openings corresponding to the spacing parts are defined in the second spacing sublayer, the groove is provided with one of the third openings and one of the fourth openings, and the one of the third openings is in communication with the one of the fourth opening.

5. The display panel of claim 4, wherein a thickness of the second spacing sublayer ranges from 0.05 microns to 0.4 microns.

6. The display panel of claim 4, wherein an opening size of one end of one of the fourth openings close to the first spacing sublayer is smaller than an opening size of corresponding one of the third openings.

7. The display panel of claim 4, wherein an etching rate of the first spacing sublayer is lower than an etching rate of the second spacing sublayer.

8. The display panel of claim 4, wherein an included angle between a connecting line at both ends of a sidewall of one of the third openings of the first spacing sublayer and a surface of the first spacing sublayer close to the array substrate is a first included angle, an included angle between a connecting line at both ends of a sidewall of one of the fourth openings of the second spacing sublayer and a surface of the second spacing sublayer close to the array substrate is a second included angle, and the first included angle is greater than the second included angle.

9. The display panel of claim 4, wherein the spacing layer further comprises a third spacing sublayer, and the third spacing sublayer is disposed between the second spacing sublayer and the planarization layer; and
a plurality of sub grooves corresponding to the spacing parts are defined in the third spacing sublayer, the groove is provided with one of the sub grooves, and an opening of each of the sub grooves faces the second spacing sublayer and is in communication with corresponding one of the fourth openings.

10. The display panel of claim 9, wherein the sidewall of the one of the fourth openings of the second spacing sublayer comprises a first curved surface, one of the sub grooves of the third spacing sublayer comprises a second curved surface, and a curvature radius of the second curved surface is greater than a curvature radius of the first curved surface.

11. The display panel of claim 10, wherein the second curved surface is continuous with the first curved surface adjacent to the second curved surface.

12. The display panel of claim 9, wherein an etching rate of the third spacing sublayer is lower than an etching rate of the second spacing sublayer.

13. The display panel of claim 9, wherein an included angle between a connecting line at both ends of a sidewall of one of the third openings of the first spacing sublayer and a surface of the first spacing sublayer close to the array substrate is the first included angle, an included angle between a connecting line at both ends of a sidewall of one of the fourth openings of the second spacing sublayer and a surface of the second spacing sublayer close to the array substrate is a second included angle, an included angle between a connecting line at both ends of a sidewall of one of the sub grooves of the third spacing sublayer and a surface of the third spacing sublayer close to the array substrate is a third included angle, the first included angle is greater than the second included angle, and the second included angle is greater than the third included angle.

14. The display panel of claim 9, wherein a thickness of the third spacing sublayer is greater than 3 nanometers.

15. The display panel of claim 4, wherein the first spacing sublayer is provided with the protrusion, a distance between an edge of the protrusion towards the center of the groove and an edge of one end of corresponding one of the fourth openings close to the first spacing sublayer is greater than or equal to 1 micron.

16. The display panel of claim 4, wherein a thickness of the first spacing sublayer ranges from 0.01 microns to 0.1 microns.

17. The display panel of claim 1, wherein one or more of the spacing parts surround corresponding one of the first electrodes.

18. The display panel of claim 17, wherein the one or more of the spacing parts are completely enclosed on a peripheral side of one of the first electrodes.

19. The display panel of claim 17, wherein the one or more of the spacing parts are partially enclosed on a peripheral side of one of the first electrodes.

20. The display panel of claim 1, wherein two of the second openings are defined between adjacent two of the first openings, two of the spacing parts are disposed between adjacent two of the first electrodes, and one of the second opening is in communication with the corresponding groove of one of the spacing parts.
